(19) United States
(12) Patent Application Publication
(10) Pub. No.: US 2025/0194154 A1
(43) Pub. Date: Jun. 12, 2025

(54) WRAP-AROUND DIELECTRIC LINER TO PREVENT BACKSIDE CONTACT TO GATE SHORT

(71) Applicant: International Business Machines Corporation, Armonk, NY (US)

(72) Inventors: Liqiao Qin, Albany, NY (US); Tao Li, Albany, NY (US); Haojun Zhang, Schenectady, NY (US); Ruilong Xie, Niskayuna, NY (US); Kisik Choi, Watervliet, NY (US)

(21) Appl. No.: 18/533,148

(22) Filed: Dec. 7, 2023

(51) Int. Cl. H01L 29/423; H01L 21/8234; H01L 23/528; H01L 29/06; H01L 29/08; H01L 29/66; H01L 29/775; H01L 29/786

(52) U.S. Cl. CPC H10D 30/6735; H01L 23/5286; H10D 30/014; H10D 30/43; H10D 30/6757; H10D 62/116; H10D 62/121; H10D 62/151; H10D 64/017; H10D 64/018; H10D 84/0135; H10D 84/0149; H10D 84/038

(57) ABSTRACT

A wrap-around dielectric structure prevents backside contacts shorting to gates in nanosheet field effect transistors (FETs). A method of making same includes providing a sacrificial layer under a nanosheet stack adjacent shallow trench isolation (STI) regions, recessing the STI regions' liner to from gaps in communication with the sacrificial layer, removing the sacrificial layer to form a cavity, and filling the cavity and gaps with a continuous dielectric material which wraps around a subsequently formed backside contact.

### BACKGROUND

The present invention relates generally to the electrical, electronic and computer arts and, more particularly, to nanosheet field effect transistors (FETs) and the like.

Backside power rails (BPR) and backside power distribution networks (BSPDN) are very attractive schemes for future complementary metal oxide semiconductor (CMOS) scaling. However, with continued scaling, a problem has arisen with regard to shorting between backside contacts and transistor gates.

FIG. 1 is a top view of aspects of a prior art integrated circuit structure. Active areas 110 and 120 are for a first FET (e.g., an NFET or a PFET) and second FET (e.g., an NFET or a PFET), respectively. The spaces between active areas are shallow trench isolation regions (STI regions) 115. Perpendicular to active areas 110/120 are gates 130 each with gate spacers 132. One of the gates 130 is shown with overlying gate contact 123. The spaces between gates 130 in an active area 110/120 are first and second source drain regions 101/102. A backside contact 140 in the first active area 110 is shown by a dotted rectangle.

FIG. 2 is a cross-gate view of the device of FIG. 1 along line Y1 in FIG. 1, during an intermediate step of processing. Line Y1 goes along a gate 130 as it traverses a first active area 110 having nanosheets 204, an STI region 115, and the second active region 120 having one or more nanosheets 204. Other features of this intermediate structure are the carrier wafer 213, back end of line (BEOL) wiring 215 (depicted at a high level), topside interlayer dielectric (ILD) 217, gate contact 123, backside dielectric layer 225, backside contact 140, dielectric layer 235, and STI regions 115 including an STI oxide 237 and STI liner 239. The dotted circle 240 highlights an area vulnerable to back side contact 140 shorting to the gate 130.

### BRIEF SUMMARY

Principles of the invention provide techniques for a wrap-around dielectric liner to prevent backside contact to gate shorts. In one aspect, an exemplary semiconductor structure includes a first active area having first and second source-drain regions; a nanosheet region of the active area interconnecting the first and second source-drain regions; a gate overlying and surrounding the nanosheet region; a direct backside contact (DBC) located below the gate in the nanosheet region; and a wrap-around dielectric liner having horizontal portions and vertical portions, wherein the horizontal portions contact the top of the direct backside contact (DBC) and the vertical portions contact sidewalls of the direct backside contact (DBC).

In another aspect, another exemplary semiconductor structure includes a first active area and a second active area each having first and second source-drain regions; a shallow trench isolation (STI) region separating the first and second active areas; a nanosheet region in each active area interconnecting the first and second source-drain regions of each active area; a gate structure over the nanosheet region of each of the first and second active areas and the isolation region; a dielectric island adjacent the shallow trench isolation (STI) region and under the nanosheet region of the second active area, the dielectric island having an upper portion; a direct backside contact (DBC) located below the nanosheet region and the second source-drain region of the first active area the direct backside contact (DBC) having an upper portion in contact with the second source-drain region of the first active area; a power rail in contact with a lower portion of the DBC direct backside contact (DBC); and a wrap-around dielectric liner wrapping the upper portion of the direct backside contact (DBC) 340 under the nanosheet region of the first active area and the upper portion of the dielectric island.

In still a further aspect, an exemplary method of forming a structure includes providing a substrate having a stack of alternating layers of nanosheets and sacrificial layers on a bottom sacrificial layer on the substrate; forming one or more openings in the substrate adjacent the stack; forming a shallow trench liner and insulation in the one or more substrate openings; recessing the shallow trench liner to form cavities; filling the cavities with a gap fill material in communication with the bottom sacrificial layer; forming a dummy gate; removing the gap fill material and bottom sacrificial layer; forming a wrap-around dielectric liner; replacing the dummy gate with a metal gate; and forming a direct backside contact (DBC) isolated from the metal gate by the wrap-around dielectric.

As used herein, “facilitating” an action includes performing the action, making the action easier, helping to carry the action out, or causing the action to be performed. Thus, by way of example and not limitation, instructions executing on a processor might facilitate an action carried out by semiconductor fabrication equipment, by sending appropriate data or commands to cause or aid the action to be performed. Where an actor facilitates an action by other than performing the action, the action is nevertheless performed by some entity or combination of entities.

Techniques as disclosed herein can provide substantial beneficial technical effects. Some embodiments may not have these potential advantages and these potential advantages are not necessarily required of all embodiments. By way of example only and without limitation, one or more embodiments allow further scaling, enhanced yield, and/or enhanced reliability for semiconductor structures using backside power rails (BPR) and backside power distribution networks (BSPDN) by reducing or eliminating shorting of direct backside contacts (DBCs) to adjacent gates.

These and other features and advantages will become apparent from the following detailed description of illustrative embodiments thereof, which is to be read in connection with the accompanying drawings.

### BRIEF DESCRIPTION OF THE DRAWINGS

The following drawings are presented by way of example only and without limitation, wherein like reference numerals (when used) indicate corresponding elements throughout the several views, and wherein:

FIG. 1 is a top-down view of a semiconductor structure in accordance with the prior art;

FIG. 2 is a view of the prior art semiconductor structure of FIG. 1 taken along line Y1 of FIG. 1;

FIG. 3 is a top-down view of a semiconductor structure in accordance with an aspect of the invention;

FIGS. 4A-4C are cross-sectional views taken along lines X1-X1′, Y1-Y1′, and Y2-Y2′, respectively, of the semiconductor structure of FIG. 3, in accordance with an aspect of the invention;

FIGS. 5A-5B are cross-sectional views taken along lines X1-X1′ and Y1-Y1′, respectively, at a starting point in the method of making the structure after forming nanosheet stacks and patterning into active areas, in accordance with an aspect of the invention;

FIGS. 6A-6B are views of the semiconductor structure of FIGS. 5A-5B after shallow trench isolation (STI) formation, in accordance with aspects of the invention, taken along lines X-X′ and Y1-Y1′, respectively;

FIGS. 7A-7B are views of the semiconductor structure of FIGS. 6A-6B after STI liner recess, in accordance with aspects of the invention, taken along lines X1, and Y1, respectively;

FIGS. 8A-8B are views of the semiconductor structure of FIGS. 7A-7B after forming a gap fill material, in accordance with aspects of the invention, taken along lines X-X′, and Y1-Y1′, respectively;

FIGS. 9A-9C are views of the semiconductor structure after dummy gate formation, in accordance with aspects of the invention, taken along lines X-X′, Y1-Y1′, and Y2-Y2′, respectively;

FIGS. 10A-10C are views of the semiconductor structure of FIGS. 9A-9C after removing bottom sacrificial layer and gap fill material, in accordance with aspects of the invention, taken along lines X-X′, Y1-Y1′, and Y2-Y2′, respectively;

FIGS. 11A-11C are views of the semiconductor structure of FIGS. 10A-10C after forming a wrap-around dielectric liner, in accordance with aspects of the invention, taken along lines X-X′, Y1-Y1′, and Y2-Y2′, respectively;

FIGS. 12A-12C are views of the semiconductor structure of FIGS. 11A-11C after etching the alternating stacks of nanosheets and sacrificial SiGe layers exposed by the dummy gate pattern and subsequently forming inner spacers and source drain material, in accordance with aspects of the invention, taken along lines X-X′, Y1-Y1′, and Y2-Y2′;

FIGS. 13A-13C are views of the semiconductor structure of FIGS. 12A-12C after replacement metal gate, in accordance with aspects of the invention, taken along lines X1, Y1, and Y2, respectively;

FIGS. 14A-14C are views of the semiconductor structure of FIGS. 13A-13C after forming MOL contacts, back end of line (BEOL) wiring, bonding a carrier wafer and removing a lower portion of substrate, in accordance with aspects of the invention, taken along lines X1, Y1, and Y2, respectively;

FIGS. 15A-15C are views of the semiconductor structure of FIGS. 14A-14C, after removing the upper portion of the substrate and the etch stop layer, in accordance with aspects of the invention, taken along lines X1, Y1, and Y2, respectively;

FIGS. 16A-16C are views of the semiconductor structure of FIGS. 15A-15C, after forming a backside dielectric film and patterning and selectively etching the film, in accordance with aspects of the invention, taken along lines X1, Y1, and Y2, respectively; and

FIGS. 17A-17C are views of the semiconductor structure of FIGS. 16A-16C, after forming a backside dielectric contact, power rails and power distribution network in accordance with aspects of the invention, taken along lines X1, Y1, and Y2, respectively.

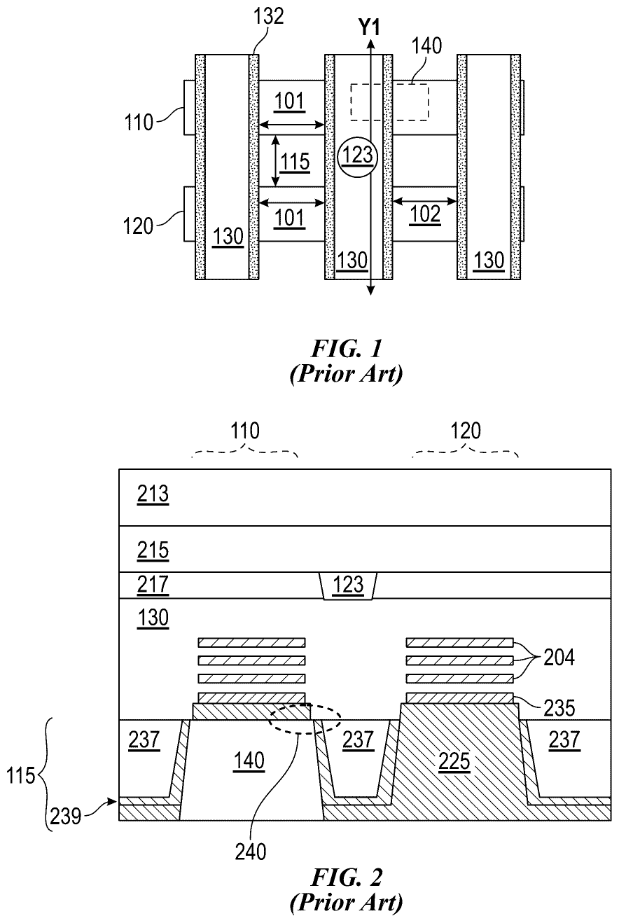

It is to be appreciated that elements in the figures are illustrated for simplicity and clarity. Common but well-understood elements that may be useful or necessary in a commercially feasible embodiment may not be shown in order to facilitate a less hindered view of the illustrated embodiments.

### DETAILED DESCRIPTION

Principles of inventions described herein will be in the context of illustrative embodiments. Moreover, it will become apparent to those skilled in the art given the teachings herein that numerous modifications can be made to the embodiments shown that are within the scope of the claims. That is, no limitations with respect to the embodiments shown and described herein are intended or should be inferred.

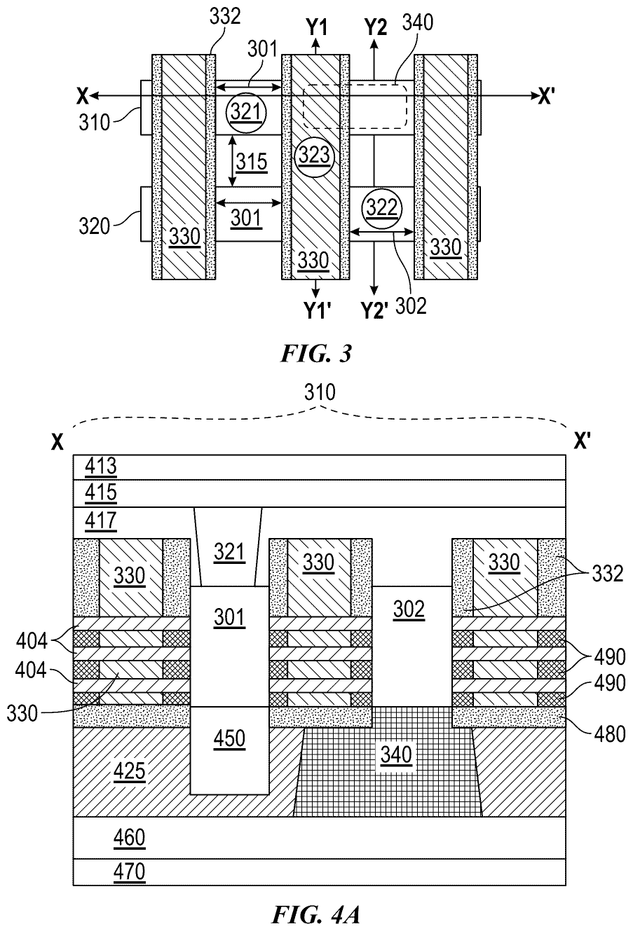

Aspects of invention provide for a wrap-around dielectric liner to prevent direct backside contacts (DBC) from shorting to gates and to techniques of fabricating the same. For orientation purposes, FIG. 3 is a top view of a structure of an exemplary embodiment with some layers removed for clarity. Referring to FIG. 3, active areas 310 and 320 are for a first FET (e.g., an NFET or a PFET) and second FET (e.g., an NFET or a PFET), respectively. The FETs can be any combination of NFETS and/or PFETs. The spaces between active areas 310/320 are shallow trench isolation regions (STI regions) 315. Perpendicular to active areas 310/320 are gates 330, preferably high-k metal gates, each with gate spacers 332. One of the gates 330 is shown with overlying gate contact 323. The spaces between gates 330 in an active area 310/320 are first and second source drain regions 301/302. In FIG. 3 the first and second source drain regions 301/302, respectively, are only shown in the second active area 320, however, they also may exist in analogous positions in the first active area 310. The source drain regions 301/302 of the active areas 310/320 have source drain contacts 321/322. In the FIG. 3 embodiment, a source drain contact 321 (e.g. source contact) is in first source drain region 301 of the first active area 310 while the second source drain contact 322 (e.g. drain contact) is in the second source drain region 302 of the second active area 320. An underlying DBC 340 in the first active area 310 is shown by a dotted rectangle.

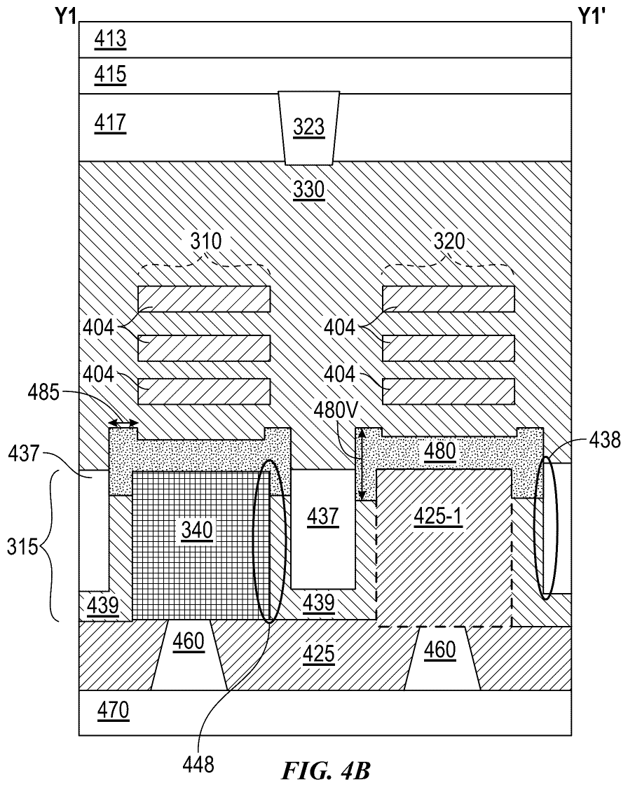

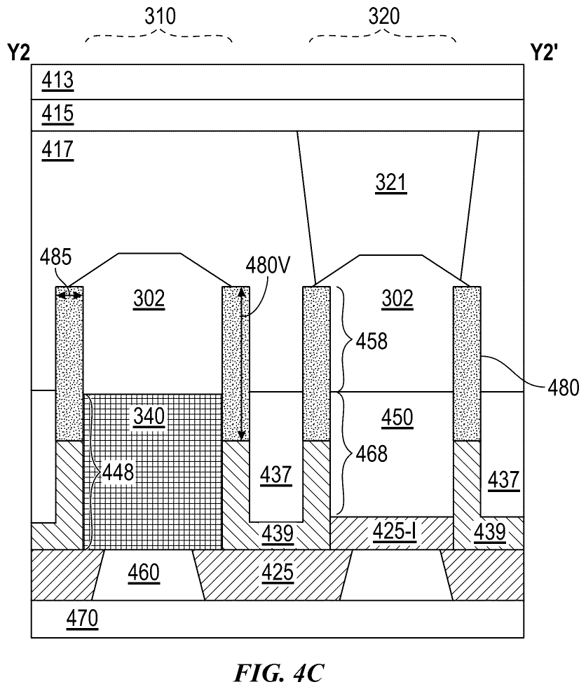

FIGS. 4A-4C are cross-section views of the device of FIG. 3 along lines X-X′, Y1-Y1′, and Y2-Y2′, respectively, of a completed semiconductor structure according to an aspect of the invention.

Referring to FIG. 4A, a cross-section along X-X′ of FIG. 3 travels along first active area 310 crossing three gates 330 having intervening source drain regions 301/302. The first source drain region 301 has an overlying first source drain contact 321 in frontside dielectric layer 417. The source drain contact 321 communicates with the backend of line wiring (BEOL) 415 shown at a high level. On top of the BEOL wiring 415 is a carrier wafer 413, made, for example, of silicon. Underlying the first source drain region 301 is a placeholder material 450 which may be SiGe. Underlying, and in contact with, the second source drain region 302 is the DBC 340. DBC 340 is in backside dielectric layer 425 (which can include, for example, one or more insulator layers, e.g. SiO₂) and in contact with backside power rail (BSPR) 460 which in turn connects to a backside power distribution network (BSPDN) 470. The first and second source drain regions 301/302 can include epitaxially grown silicon and can include dopants. The DBC 340 is isolated from the gate 330 by a combination of wrap-around dielectric liner 480 and inner spacers 490. In this X-X′ view, the wrap-around dielectric liner 480 appears planar and underlies the gate 330 and inner spacers 490 while an opening in the wrap-around dielectric liner 480 allows the BDC 340 to connect with the second source drain region 302. Wrap-around dielectric liner 480 can be SiCO, SiCOH, SiBCN, SiCON, Aluminum Oxide, or other suitable material. Note that, as will be seen when describing the method, wrap-around dielectric liner 480 and gate spacers 332 in one or more embodiments may be formed from the same material. Inner spacers 490 may be SiCO, SiBCN, SiCON, Aluminum Oxide, or other suitable material. The gates 330 are, for example, high-k metal gates which wrap the stacked nanosheets 404 (which can be made, for example, from silicon and which can be doped).

Referring to FIG. 4B, a cross-section along Y1-Y1′ of FIG. 3 travels along gate 330 over nanosheets 404 of the first active area 310, across the STI region 315, and over another nanosheet stack of the second active area 320. The wrap-around dielectric liner 480 is located under nanosheets 404 of active areas 310/320. In particular, the wrap-around dielectric liner 480 wraps a corner around the top of and the upper sidewalls of the DBC 340 in the first active area 310 in a seamless fashion. This continuous wrap around film, as opposed to two different depositions on horizontal and verticals surfaces, aids in reliability because interfaces (for example where a separate horizontal and vertical deposits meet) are weak points that can fail either due to the expansion and contraction of different materials during heating cycles and/or chemical incursion during the DBC 340 forming process. The wrap-around dielectric 480 prevents shorting of the DBC 340 to the gate 330. Similarly, the wrap-around dielectric layer 480 can wrap around the top of, and the upper sidewalls of, the dielectric island 425-I (dotted area of backside dielectric 425) under the second active area 320. The dielectric island 425-I can be delineated by STI region 315 on either side, the wrap-around dielectric 480 on top, and its bottom even with the lower interface of the STI liner 439. In each case (wrapping around DBC 340 or dielectric island 425-I of the active areas 310/320), a vertical portion 480V of the wrap-around dielectric 480 is above the STI liner 439. As a result, the wrap-around dielectric liner vertical portion 480V and STI liner 439 have the same width 485 within patterning process tolerances.

Still referring to FIG. 4B, the STI oxide 437 is contacted by different materials depending upon the vertical location of its sidewall 438. On the lower sidewalls, there is STI liner 439 and on the upper sidewalls there is a vertical portion 480V of the wrap-around dielectric 480. The vertical portion 480V of the wrap-around dielectric liner can span from 1% up to one-half of the height of the sidewall 438 of the STI oxide 437; in some embodiments it spans 10% to 50%; in other embodiments 20% to 50%; in one or more advantageous embodiments the vertical portion 480V of the wrap-around dielectric liner covers 20%-40% of the sidewall 438 of the STI oxide 437. Similarly, DBC 340 is contacted by different materials depending upon the vertical location of its sidewall 448. On the lower sidewalls, there is STI liner 439 and on the upper sidewalls there is a vertical portion 480V of the wrap-around dielectric 480. The vertical portion 480V of the wrap-around dielectric liner can span from 1% up to one-half of the height of the sidewall 448 of the DBC 340; in some embodiments it spans 10% to 50%; in other embodiments 20% to 50%; in a one or more advantageous embodiments the vertical portion 480V of the wrap-around dielectric liner covers 20%-40% of the sidewall 448 of the DBC 340.

Referring to FIG. 4C, a cross-section taken in the Y2-Y2′ direction of FIG. 3 is illustrated. This direction is offset and parallel to the gate 330 and traverses STI regions 315 (including STI oxide 437 and STI liner 439) and first and second active areas 310/320, respectively, each active area 310/320 having a second source drain region 302. In the first active area 310, the DBC 340 contacts the bottom of the second source drain region 302. In the second active area 320, a placeholder material 450 contacts the bottom of the second source drain region. In this view, vertical portions 480V of the wrap-around dielectric layer 480 are on an upper portion of the sidewall 448 of DBC 340 in first active area 310 while STI liner 439 is on lower portions. In this view, vertical portions 480V of the wrap-around dielectric layer 480 are on the length of sidewall 458 of second source/drain region 302 while STI liner 439 is not. In this view, vertical portions 480V of the wrap-around dielectric layer 480 is on an upper portion of sidewall 468 of placeholder material 450 of the second active area 320 while STI liner 439 is on the lower portion. In both cases, the vertical portion 480V of wrap-around dielectric layer 480 is above the STI liner 439. In one or more embodiments, within the limits of processing tolerances, the STI liner 439 is the same width 485 as the vertical portion 480V of the wrap-around dielectric 480. The percentage of vertical portions 480V of the wrap-around dielectric layer 480 on the length of the sidewall 448 of the DBC 340 may be as described in conjunction with FIG. 4B.

Comparing views in FIGS. 3, 4A, 4B, and 4C of the DBC 340, the DBC 340 has different sidewall coverage depending on which orientation is viewed. For example, in FIG. 4B's Y1-Y1′ cross-section, this is the only view having the wrap-around dielectric 480 on the entire top surface of the DBC 340 and a portion of the sidewalls 448. However, referring to FIG. 4C (Y2-Y2′ direction), DBC 340 sidewalls 448 are in contact with the vertical portion 480V of wrap-around dielectric 480 stacked over the STI liner 439 having the same width, in one or more embodiments, within the limits of processing tolerances. However, the same DBC 340, when viewed in the X-X′ direction (FIG. 4A), is not bound by the stack (vertical portion 480V of wrap-around dielectric 480 and STI liner 439 having about the same width); instead, in the X-X′ orientation, the sidewall of the DBC 340 largely contacts backside dielectric 425 while a top surface of the DBC 340 contacts a horizontal portion of the wrap-around dielectric 480 and a second source drain region 302.

Certain aspects of FIGS. 3 and 4A-4C should be noted. First, referring to FIGS. 3 and 4A, within an active region (here first active region 310), the backside 340 and front side source drain contacts 321 do not overly each other, but instead are separated by a portion of an intervening gate 330 structure including any gate spacers 332 or inner spacers 490. For example, DBC 340 to second source/drain materials 302 are not directly underneath the source/drain contact 321 to the first source drain area on the front side.

An exemplary method of making the semiconductor structure described in FIGS. 3 and 4A-4C will now be discussed.

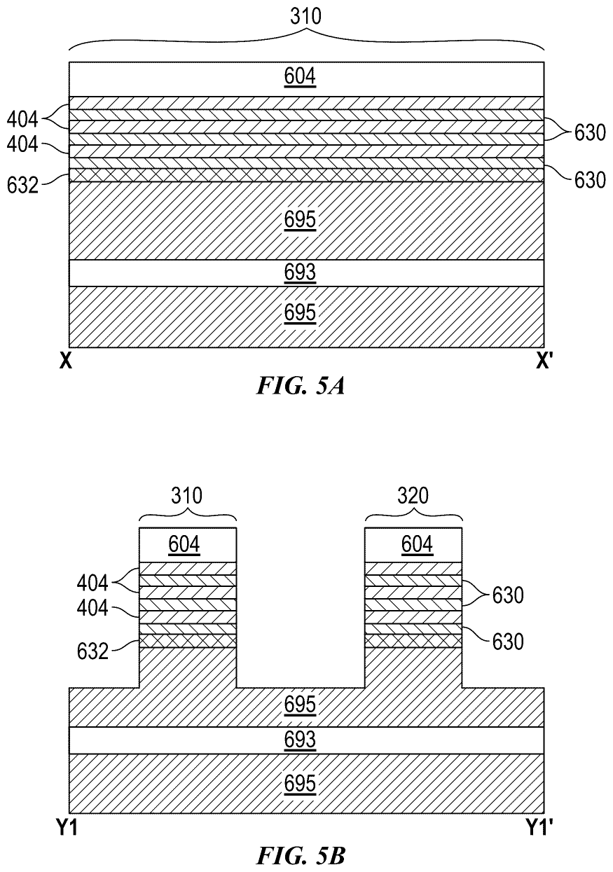

Referring to FIGS. 5A-B, which are cross-sections along the same directions as previously described, a starting point is a substrate (e.g. silicon) 695 having an embedded etch stop layer 693 which may be SiGe. On top of the substrate 695 is a bottom sacrificial layer 632 which may be a SiGe layer with Ge doping greater than or equal to about 2%. On top of the bottom sacrificial layer is an alternating stack of sacrificial SiGe layers 630 (having lower doping than the bottom sacrificial layer 632) and nanosheets 404 which may be Si. In FIG. 5A (X-X′ direction) and 5B (Y1-Y1′), the stacks have been etched to form first and second active areas 310/320, respectively. Note the cross-section of the Y2-Y2′ direction looks the same as Y-Y1′ (FIG. 5B) cross-section at this point in the process and is therefore not shown. These active areas 310/320 will subsequently be used to form first transistors (FET1) and second transistors (FET2) which may be any combination of N and/or P transistors. On top of the active areas 310/320 is a hardmask 604.

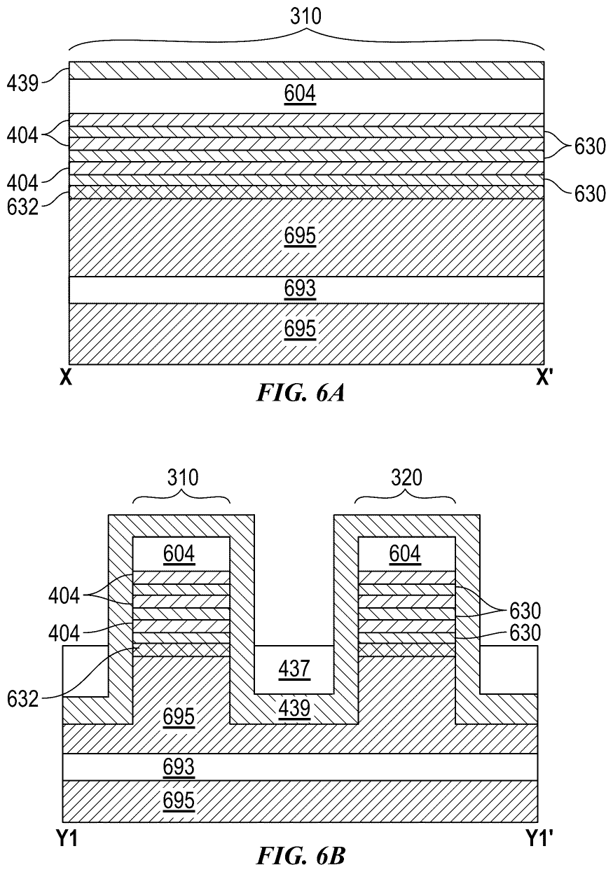

FIGS. 6A-6B show views corresponding to FIGS. 5A-5B, after shallow trench isolation (STI) formation, in accordance with aspects of the invention. In particular, a STI liner 439 is formed between the active areas 310/320 which is then filled with STI insulator 437; the STI insulator is polished to be co-planar with the STI liner 439 at the top of the active areas 310/320 and then STI insulator 437 is recessed such that the STI liner 439 covered active areas 310/320 are revealed. The STI liner 439 material may be silicon nitride or other suitable material while the STI insulator 437 material may be silicon dioxide or other suitable material. As with FIGS. 5A and 5B, in FIGS. 6A and 6B, the Y1-Y1′ and Y2-Y2′ direction views are the same at this point in the process, thus only Y1-Y1′ (FIG. 6B) is expressly depicted.

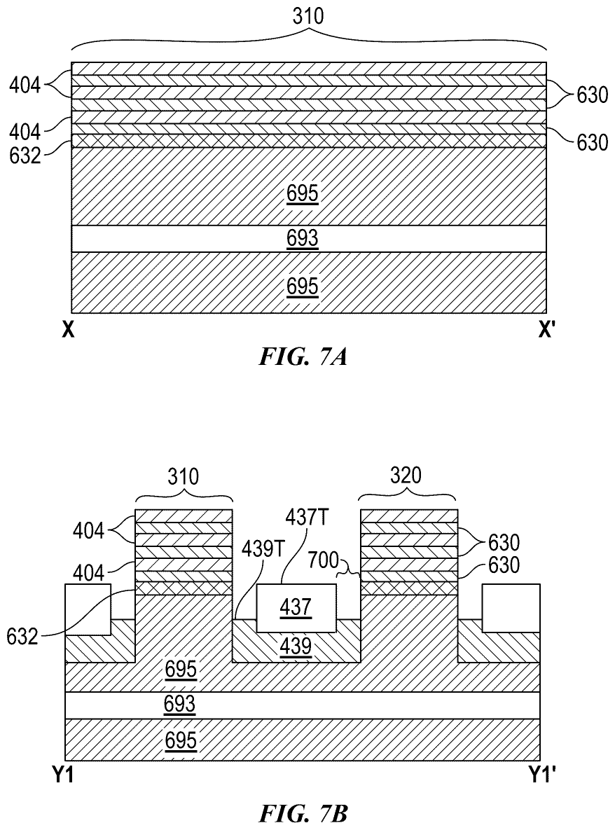

FIGS. 7A-7B show views corresponding to FIGS. 6A-B, after STI liner 439 recess, in accordance with aspects of the invention. Referring to FIG. 7B the top surface of the STI liner 439T is recessed below the top surface of STI insulator 437T, thereby creating a gap 700 between the sidewall of the STI insulator 437 and the opposite sidewall comprising the bottom sacrificial layer 632 and a portion of the substrate 695.

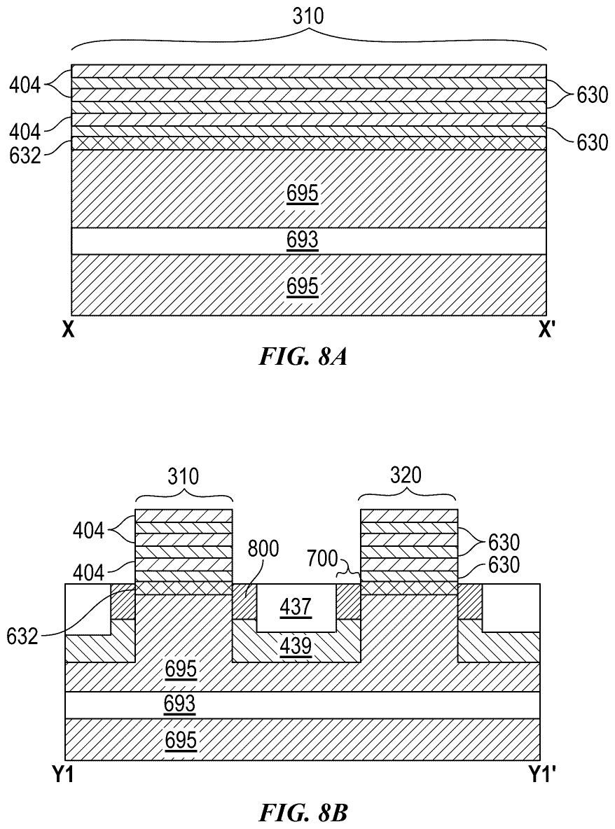

FIGS. 8A-8B show views corresponding to FIGS. 7A-7B, after forming a gap fill material 800 in the gap 700 in accordance with an aspect of the invention. Gap fill material 800 will be sacrificial and accordingly may be titanium oxide or other suitable material. The gap fill material 800 can be formed, for example, to be coplanar (within processing tolerances) with the STI insulator 437.

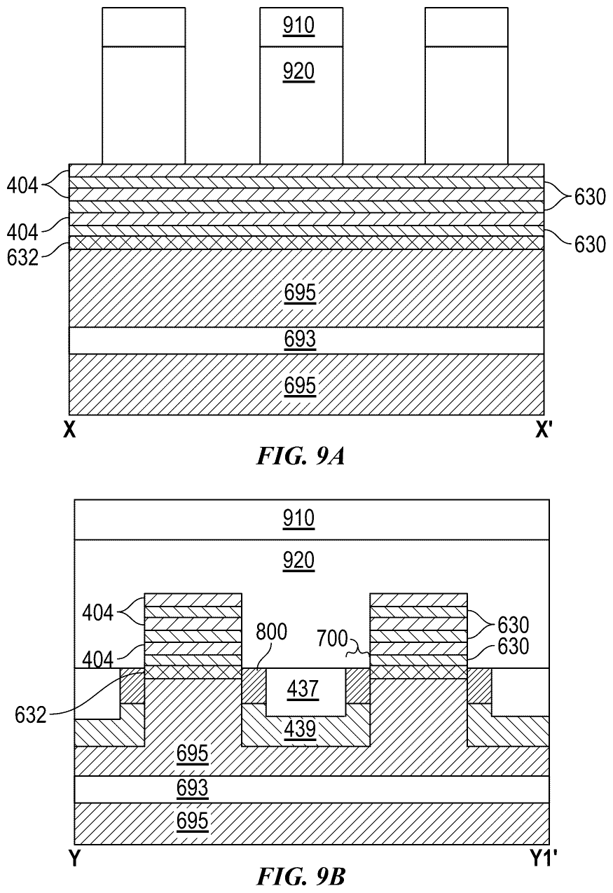

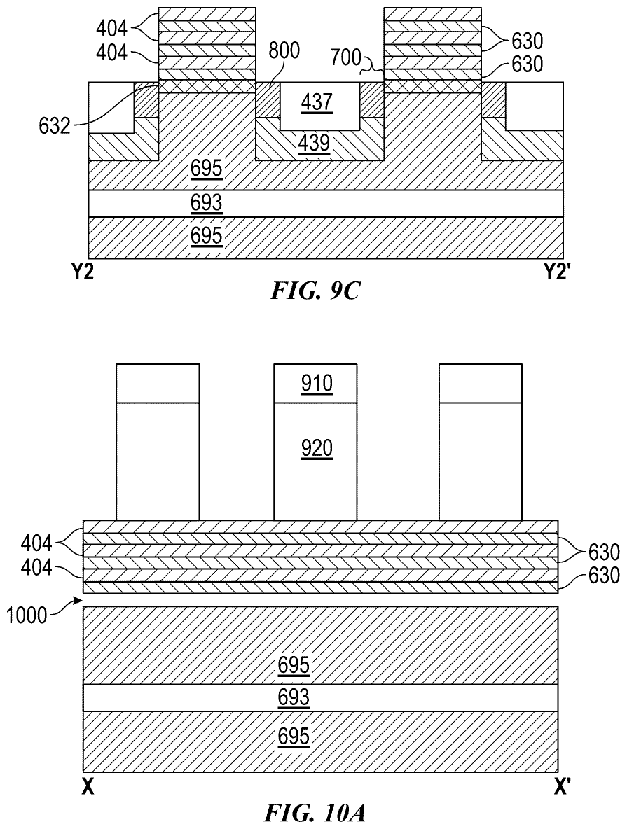

FIGS. 9A-9C show views corresponding to FIGS. 8A-8B, after forming a patterned hardmask 910 and dummy gate 920. With the patterning, now the views along the Y1-Y1′ (B FIGS.) and Y2-Y2′ (C FIGS.) become different because Y1-Y1′ will be along a gate and Y2-Y2′ will be parallel but not containing the gate. Accordingly, FIG. 9C is added to show the cross-section in the Y2-Y2′ direction.

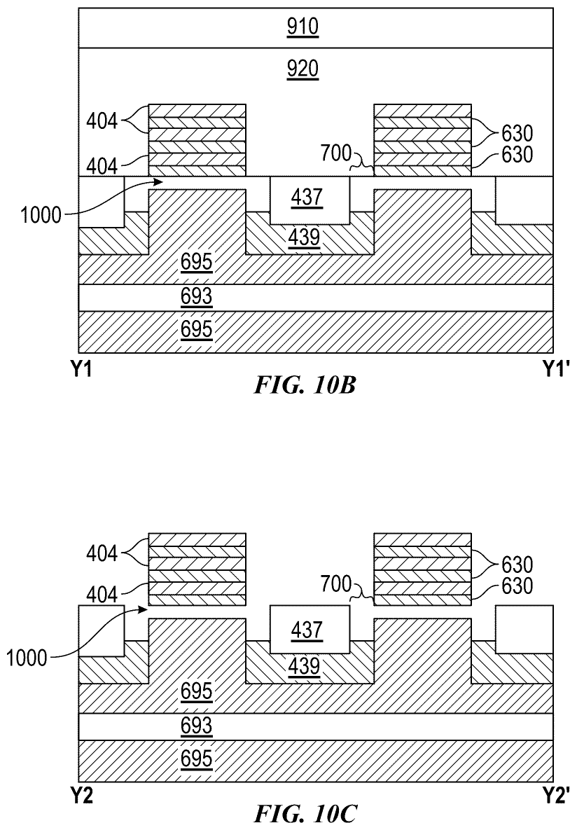

FIGS. 10A-10C show views corresponding to FIGS. 9A-9C, after removing bottom sacrificial layer 632 and sacrificial gap fill material 800. Removing the bottom sacrificial layer 632 creates a cavity 1000 located under the alternating nanosheet 404/SiGe layer 630 structure, specifically between the structure's lowest SiGe layer 630 and substrate 695. Removing the gap fill material 800 recreates the gap 700 above the STI liner 439 and adjacent the STI insulator 437. The cavity 1000 and gap 700 are connected to each other as seen in FIGS. 10B-10C. At this stage, the structure is not “floating” despite the appearance in the figures—all the nanosheets are supported elsewhere by the dummy gate material, so they are stable.

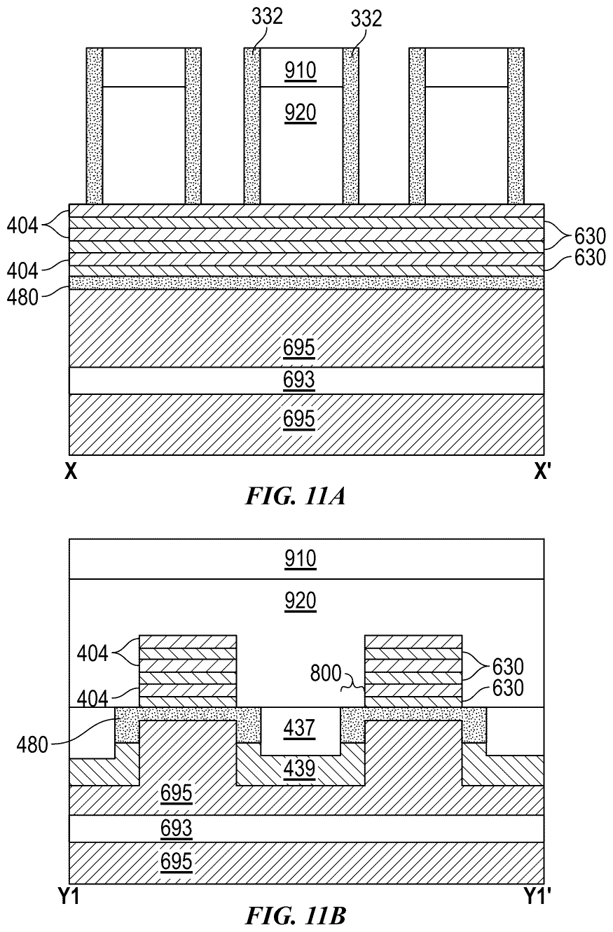

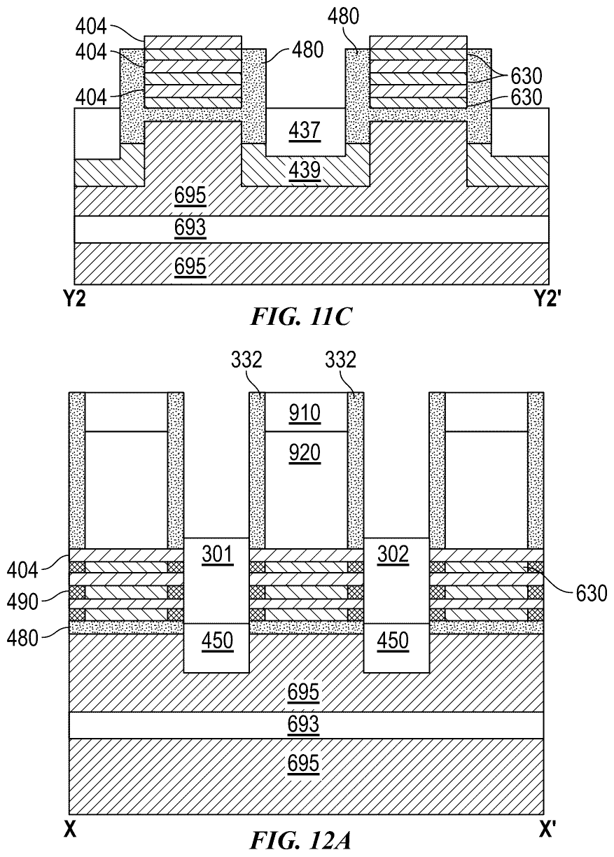

FIGS. 11A-11C show views corresponding to FIGS. 10A-10C, after forming a wrap-around dielectric liner 480. In addition, the same material forms spacers 332 around the dummy gate 920 (FIG. 11A). Referring to FIGS. 11B-C, the wrap-around dielectric liner 480 forms in the former cavity 1000 and gap 800 of FIGS. 10B-C. As a result, the STI insulator 437 is lined by two materials, namely on the bottom and the lower sidewalls by STI liner 439 and on the upper sidewalls by the wrap-around dielectric 480 (see FIGS. 11B-C). Referring to FIGS. 11B-11C, the wrap-around dielectric layer 480 wraps around the bottom SiGe layer 630 and up the sidewalls to cover the sidewalls of alternating layers of nanosheet 404 and sacrificial SiGe layers 630 leaving the top surface of uppermost nanosheet 404 and part of its sidewall exposed.

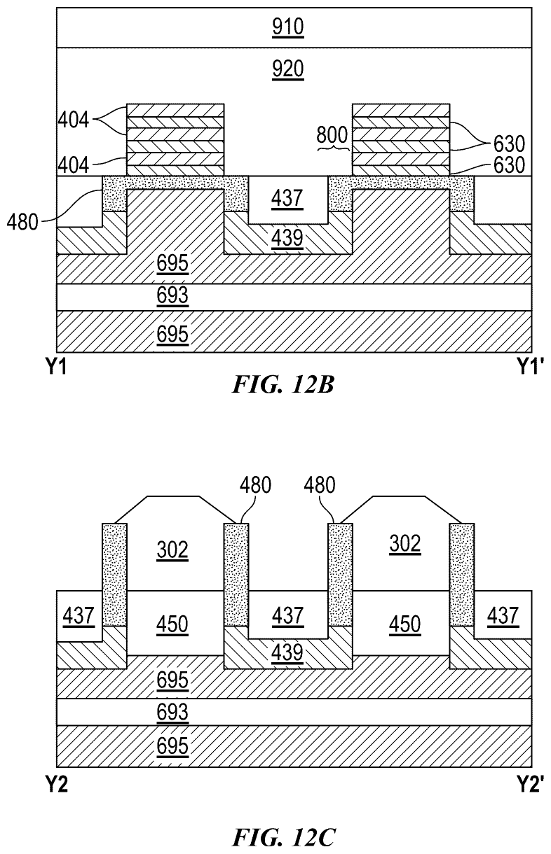

FIGS. 12A-12C show views corresponding to FIGS. 11A-11C, after etching the stack of alternating nanosheets 404 and sacrificial SiGe layers 630 exposed by the dummy gate 920 patterning. Etching the stacks using the dummy gate patterns leaves portions of the substrate 695 exposed and the etched sidewalls of the alternating stack exposed. With respect to the exposed surfaces of the etched stack in the X-X′ direction (FIG. 12A), sacrificial SiGe layers 630 are recessed relative to the exposed surfaces of nanosheets 404 using known selective etching techniques. In the recesses, an inner spacer 490 is formed horizontally adjacent the SiGe layer 630 (see FIG. 12A).

With respect to the exposed surfaces of the substrate 695 in FIGS. 12A and 12C, the substrate is further etched to transfer the dummy gate patterns into the substrate to a depth less than that of the STI liner 439 (see FIG. 12C). The etched substrate is then filled with a bottom placeholder material 450, which may be silicon germanium (SiGe), to a level even, in one or more embodiments, within process tolerances, with the top of the STI insulator 437 in the Y2-Y2′ direction (see FIG. 12C) and even, within process tolerances, with the top of the wrap-around dielectric 480 in the X-X′ direction (see FIG. 12A). On top of the bottom placeholder material 450, a source/drain material is formed. Preferably, the source/drain material is epitaxially grown silicon. Referring to FIG. 12 A (X-X′ direction), along a particular active area (e.g. 320), the source drain regions are denoted first source drain 301 and second source drain 302 on either sides of a dummy gate 920.

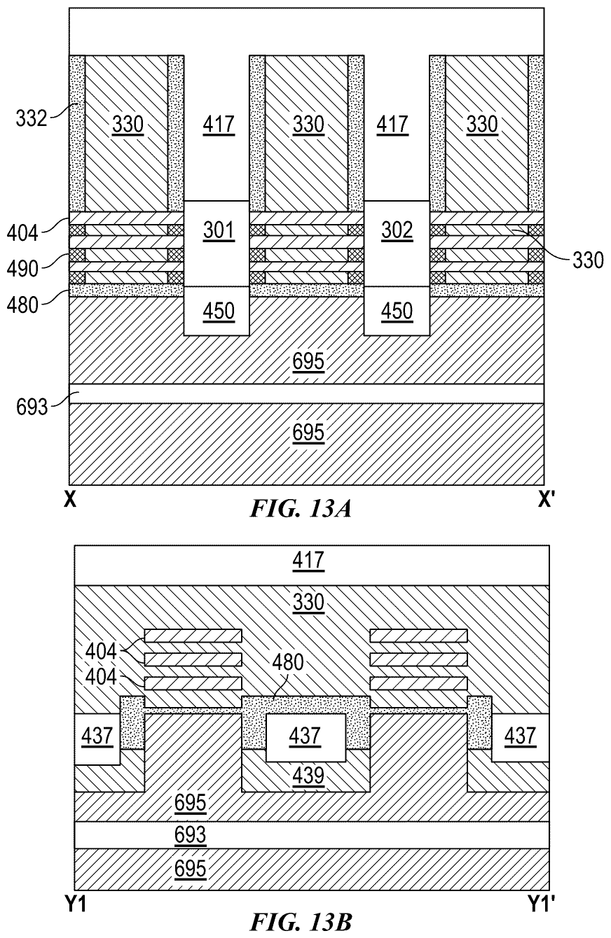

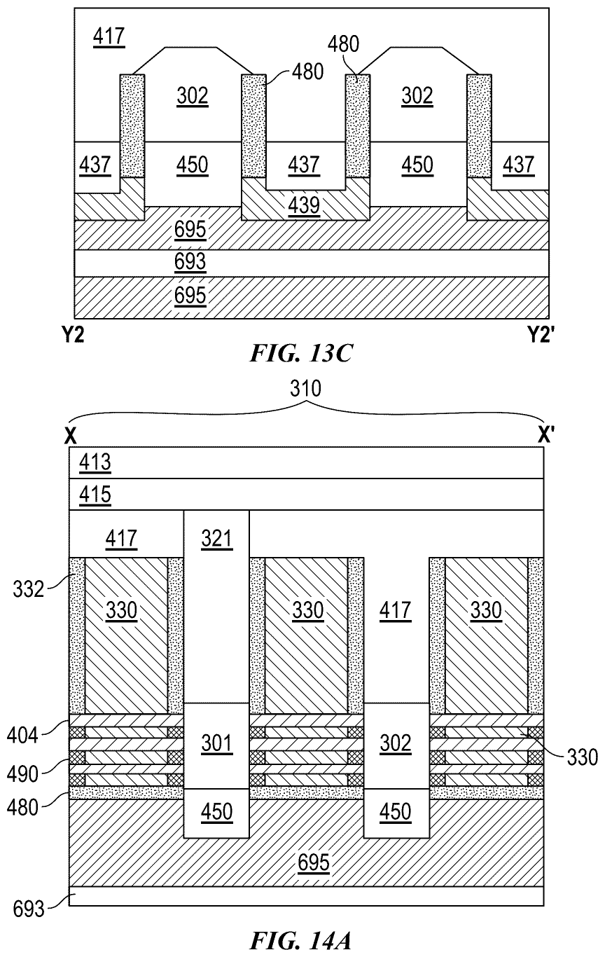

FIGS. 13A-13C show views corresponding to FIGS. 12A-12C, after forming a planar frontside dielectric layer 417 and replacing the dummy gates 920 and Sacrificial SiGe layers 630 with high-k metal gate (HKMG) structures 330. The frontside dielectric may be one or more layers of insulators such as SiO₂, SiN used for middle of line (“MOL”) levels. The HKMG structure 330 is a multi-layer structure whose composition of layers is known to those skilled in the art. Due to the cleaning processes prior to HKMG deposition, any exposed STI insulator 437 (e.g. Y1-Y1′ direction of FIG. 13B) may be recessed relative to STI insulator 437 protected by frontside dielectric 417 during the cleans (e.g. Y2-Y2′ direction of FIG. 13C).

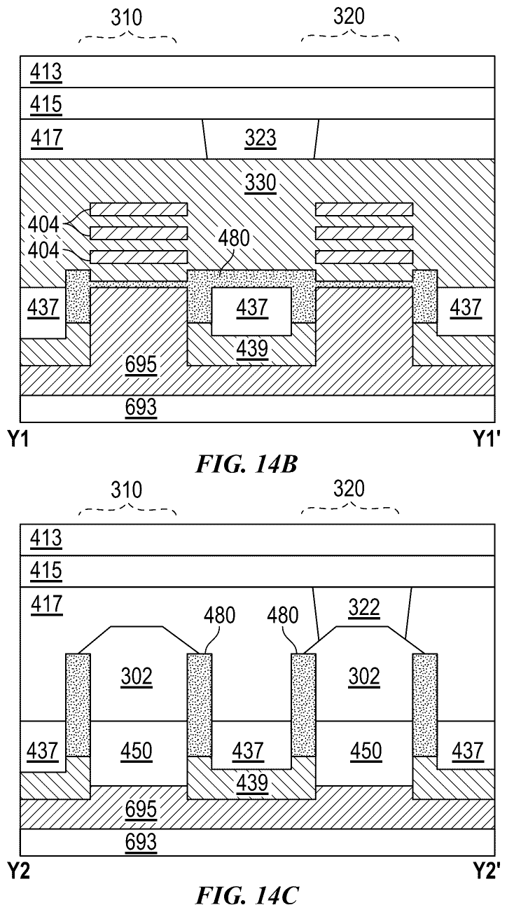

FIGS. 14A-14C show views corresponding to FIGS. 13A-13C, after forming MOL contacts, back end of line (BEOL) wiring 415, bonding a carrier wafer 413 and removing a lower portion of substrate 695. MOL contacts include source/drain contacts 321/322 and gate contact 323. In the FIG. 14A view, the source/drain contact 321 to the first source/drain region 301 is in the first active area 310. In the FIG. 14C view, the source/drain contact 322 to the second source/drain region 302 is in the second active area 320. After contact formation, BEOL wiring 415 is completed. Then a carrier wafer 413 is attached to the BEOL wiring 415 on the front side the structure. After carrier attachment, attention turns to the backside of the structure where the lower portion of substrate is removed to expose etch stop layer 693.

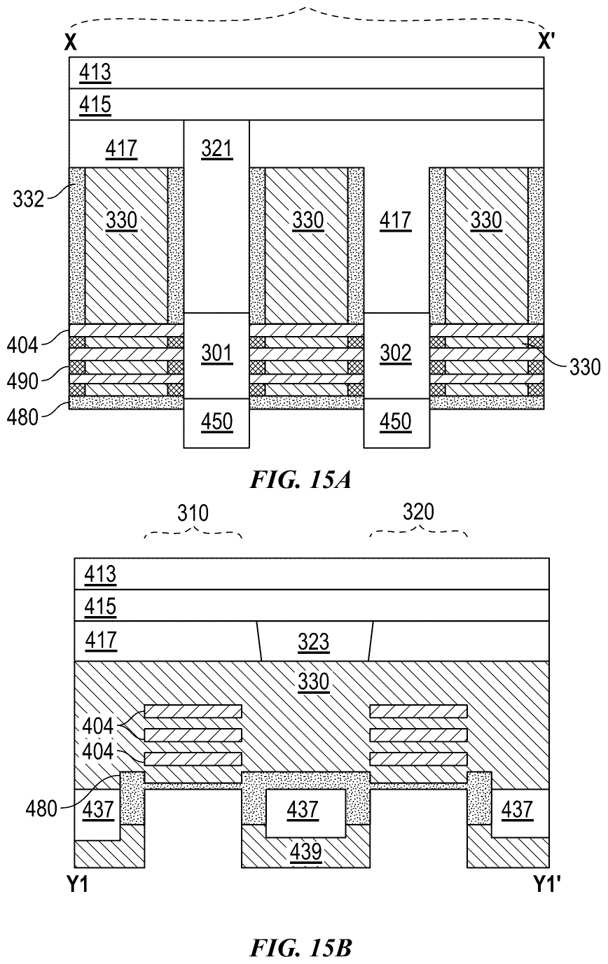

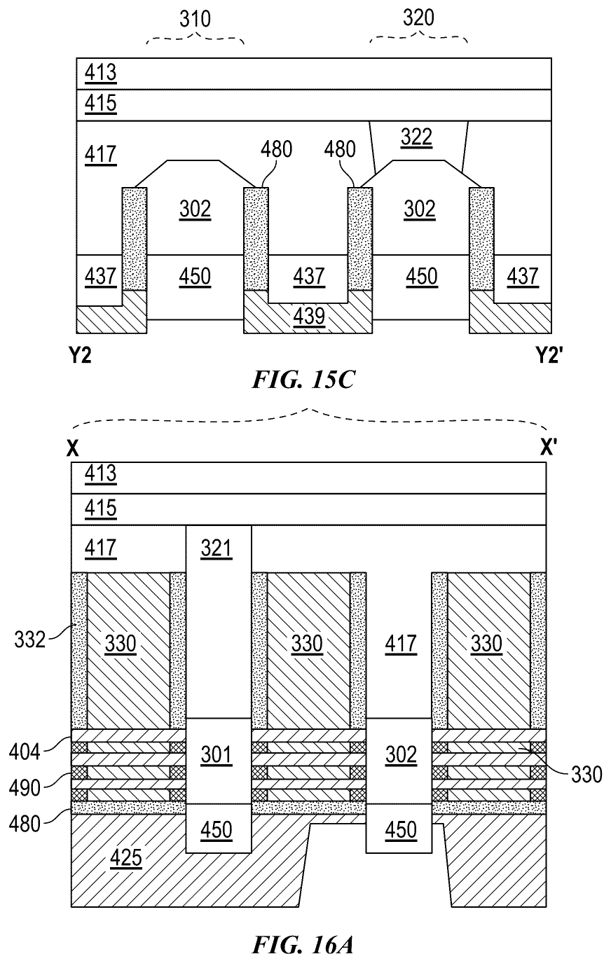

FIGS. 15A-15C show views corresponding to FIGS. 14A-14C, after removing the etch stop layer 693 and the upper portion of the substrate 695; as a result, the STI liner 439, wrap-around dielectric 480 and the bottom place holder material 450 become exposed in preparation of forming DBCs.

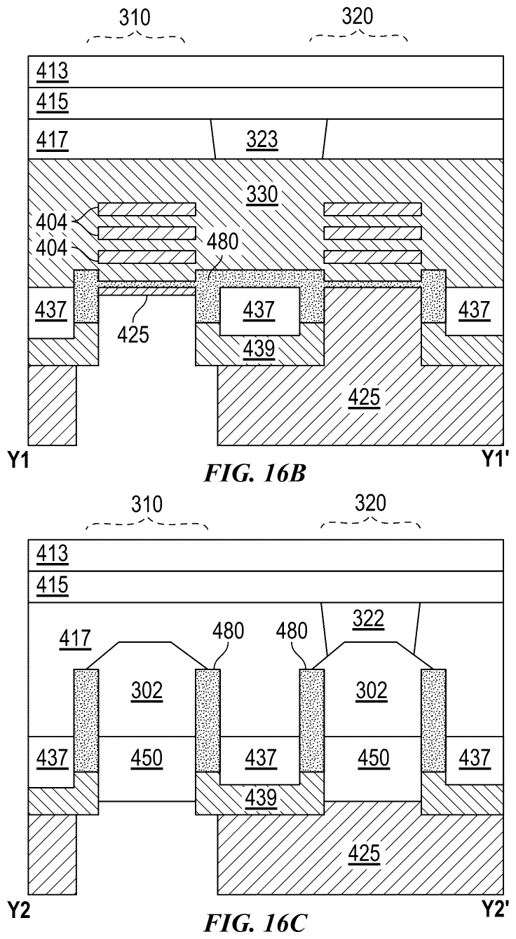

FIGS. 16A-16C show views corresponding to FIGS. 15A-15C, after forming a backside dielectric film 425 and patterning and etching the film using known techniques, including optical planarization layers (not shown), hardmask (not shown) and selective etching of the oxide-based backside dielectric film 425 to nitride based STI liner 439, thereby exposing the bottom placeholder material 450 (see FIGS. 16A and 16C). Due to the combination of film thicknesses, dimensions of the pattern, and etch selectivity, advantageously, in some cases, some backside dielectric film 425 remains just below the wrap-around dielectric (see FIG. 16A) or around exposed bottom placeholder material 450 (see FIG. 16B).

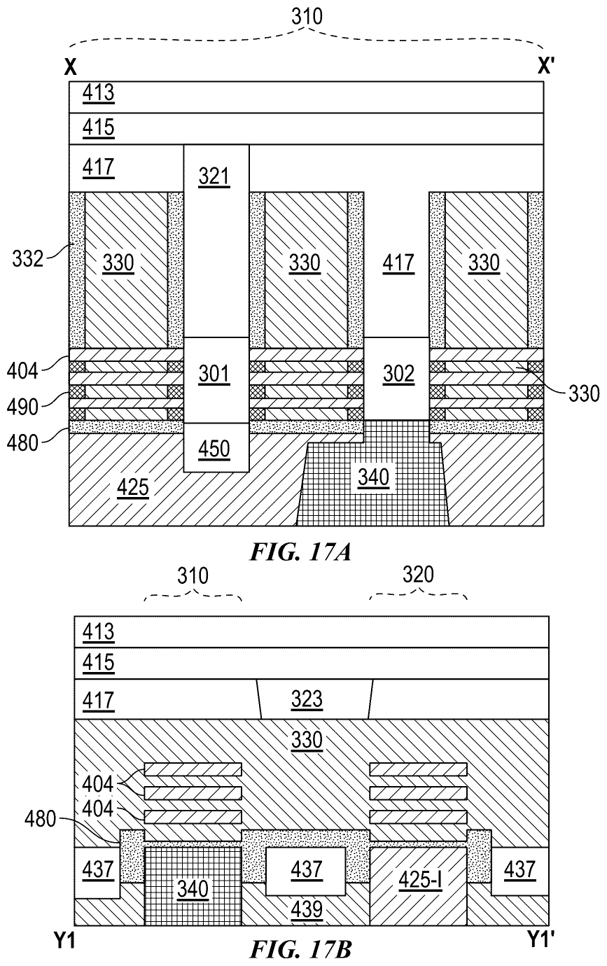

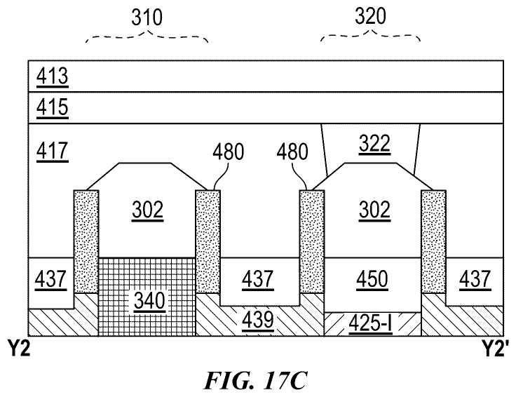

FIGS. 17A-17C show views corresponding to FIGS. 16A-16C, after removing the bottom placeholder material 450 previously exposed by the openings in the backside dielectric film 425, thereby exposing second source/drain material 302 in the first active area 310 (see FIG. 17A) and in the second active area 320 (see FIG. 17C). During the removal process, any remaining backside dielectric film 425 in the openings is also removed to expose wrap-around liner 480 under active area 310 (see FIG. 17B). A pre-silicide clean is performed prior to DBC 340 deposition. A DBC can include, for example, a silicide layer in contact with the second source-drain 302 materials, liner materials, and a bulk fill which includes a metal such tungsten or cobalt. The DBC materials are polished to be coplanar the bottom surface of the STI liner 439 which leaves backside oxide islands 425-I under the second active area (See FIGS. 17A and 17C).

Adding another oxide-based backside dielectric layer, patterning it, and forming damascene power rails 460, and adding a power distribution network 470 to FIGS. 17A-17C results in the completed structure described in FIGS. 4A-4C.

Bulk silicon is a non-limiting example of a suitable substrate 695 material or carrier wafer 413 material; other materials are also possible.

In summary, aspects of the invention include semiconductor structure having a first active area with first and second source-drain regions 310/320; a nanosheet region 404 of the active area interconnecting the first and second source-drain regions; a gate 330 overlying and surrounding the nanosheet region; a direct backside contact (DBC) 340 located below the gate in the nanosheet region; and a wrap-around dielectric liner 480 having horizontal portions and vertical portions 480-V, wherein the horizontal portions contact the top of the direct backside contact (DBC) and the vertical portions contact sidewalls of the direct backside contact (DBC). The wrap-around material 480 can be SiCO, SiBCN SiCON, and Aluminum Oxide. Further, the vertical portion 480-V of wrap-around dielectric liner 480 can contact sidewalls of the second source-drain 320 of the first active area 310 and sidewalls of the direct backside contact (DBC) 340.

The structure can also include a gate spacer 332 on opposing verticals sides of the gate 330, wherein the gate spacer and the wrap-around dielectric liner 480 are the same material; and a back side power rail (BSPR) 460 in contact the direct backside contact (DBC) 340. The direct backside contact (DBC) 340 contacts the second source-drain region 320. (See FIGS. 3 and 4C).

The structure can also include a frontside contact 321 to the first source-drain region 310 wherein the frontside contact does not overlay the direct backside contact (DBC) 340.

In addition, a second active area 302 having another source drain region 301 and a second nanosheet 404 region wherein the gate 330 overlies and surrounds the second nanosheet region can be present, where a dielectric island 425-I under the second nanosheet region. Here, the wrap-around dielectric liner 480 can be located on a top surface and a portion of the sidewalls of the dielectric island (See FIG. 4B). Furthermore, the vertical portion 480-V of wrap-around dielectric liner 480 is in contact with the other source-drain (See FIG. 4C). Advantageously, there can be a placeholder material 450 under the other source drain region wherein the vertical portion 480-V of wrap-around dielectric liner 480 is in contact with an upper portion of the sidewall 468 placeholder material (See FIG. 4C).

Referring to FIG. 4B, other features of the semiconductor may include a shallow trench isolation (STI) region separating the first and second active regions 310/320 wherein the shallow trench isolation (STI) region comprises a shallow trench isolation (STI) liner 439 and a shallow trench isolation (STI) insulator 437 and is located under the vertical portion 480-V of the wrap-around dielectric liner 480 and contacts sidewalls 448 of the direct backside contact BCD 340. The shallow trench isolation (STI) liner 439 and the vertical portion 480-V of the wrap-around dielectric liner 480 have the same width (within process tolerances). The shallow trench isolation (STI) liner 439 and the wrap-around dielectric liner 480 may be different materials. The vertical portion 480-V of the wrap-around dielectric liner 480 is from about 1% to about 50% of a sidewall 448 of the direct backside contact BCD 340.

In summary, other aspects of the invention include semiconductor structure a first active area 310 and a second active area 320 each having first and second source-drain regions 301/302; a shallow trench isolation (STI) region 315 separating the first and second active areas; a nanosheet region 404 in each active area 310/320 interconnecting the first and second source-drain regions 301/302 of each active area; a gate structure 330 over the nanosheet region 404 of each of the first and second active areas and the isolation region 315; a dielectric island 425-I adjacent the shallow trench isolation (STI) region 315 and under the nanosheet region 404 of the second active area 320, the dielectric island 425-I having an upper portion; a direct backside contact (DBC) 340 located below the nanosheet region 404 and the second source-drain region 302 of the first active area 310 the direct backside contact (DBC) 340 having an upper portion in contact with the second source-drain region 302 of the first active area 310; a power rail 460 in contact with a lower portion of the DBC direct backside contact (DBC) 340; and a wrap-around dielectric liner 480 wrapping the upper portion of the direct backside contact (DBC) 340 under the nanosheet region 404 of the first active area 310 and the upper portion of the dielectric island 425-I.

Referring to FIG. 4C, the wrap-around dielectric liner 480 has a vertical portion 480-V in contact with the second source-drain 302 of the first active area region 310 and the direct backside contact (DBC) 340. The vertical portion 480-V can contact the second source-drain 302 of the second active area region 320 and can contact a placeholder material 450 located under the second source-drain 302 of the second active area region 320.

In further summary, aspects of the invention include a method of forming a structure including providing a substrate 695 having a stack of alternating layers of nanosheets 404 and sacrificial layers 630 on a bottom sacrificial layer 632 on the substrate 695 (See FIG. 5); forming one or more openings in the substrate adjacent the stack; forming a shallow trench liner 439 and insulation 437 in the one or more substrate openings (FIG. 6); recessing the shallow trench liner 439 to form cavities 700 (FIG. 7); filling the cavities 700 with a gap fill material 800 in communication with the bottom sacrificial layer 632 (FIG. 8B); forming a dummy gate 920 (FIG. 9); removing the gap fill material 800 and bottom sacrificial layer 632 (FIG. 10); forming a wrap-around dielectric liner 480 (FIG. 11); replacing the dummy gate 920 with a metal gate 330 (FIG. 13); and forming a direct backside contact (DBC) 340 isolated from the metal gate 330 by the wrap-around dielectric 480 (FIG. 17).

Aspects of the method can also include forming inner spacers 490 under the alternating layers of nanosheets 404 and adjacent the sacrificial layers 630 (FIG. 12); and forming a power rail 460 in contact with the direct backside contact (DBC) 340 (FIG. 4).

Semiconductor device manufacturing includes various steps of device patterning processes. For example, the manufacturing of a semiconductor chip may start with, for example, a plurality of CAD (computer aided design) generated device patterns, which is then followed by effort to replicate these device patterns in a substrate. The replication process may involve the use of various exposing techniques and a variety of subtractive (etching) and/or additive (deposition) material processing procedures. For example, in a photolithographic process, a layer of photo-resist material may first be applied on top of a substrate, and then be exposed selectively according to a pre-determined device pattern or patterns. Portions of the photo-resist that are exposed to light or other ionizing radiation (e.g., ultraviolet, electron beams, X-rays, etc.) may experience some changes in their solubility to certain solutions. The photo-resist may then be developed in a developer solution, thereby removing the non-irradiated (in a negative resist) or irradiated (in a positive resist) portions of the resist layer, to create a photo-resist pattern or photo-mask. The photo-resist pattern or photo-mask may subsequently be copied or transferred to the substrate underneath the photo-resist pattern.

There are numerous techniques used by those skilled in the art to remove material at various stages of creating a semiconductor structure. As used herein, these processes are referred to generically as “etching”. For example, etching includes techniques of wet etching, dry etching, chemical oxide removal (COR) etching, and reactive ion etching (RIE), which are all known techniques to remove select material(s) when forming a semiconductor structure. The Standard Clean 1 (SC1) contains a strong base, typically ammonium hydroxide, and hydrogen peroxide. The SC2 contains a strong acid such as hydrochloric acid and hydrogen peroxide. The techniques and application of etching is well understood by those skilled in the art and, as such, a more detailed description of such processes is not presented herein.

Although the overall fabrication method and the structures formed thereby are novel, certain individual processing steps required to implement the method may utilize conventional semiconductor fabrication techniques and conventional semiconductor fabrication tooling. These techniques and tooling will already be familiar to one having ordinary skill in the relevant arts given the teachings herein. For example, the skilled artisan will be familiar with epitaxial growth, self-aligned contact formation, formation of high-K metal gates, and so on. The term “high-K” has a definite meaning to the skilled artisan in the context of high-K metal gate (HKMG) stacks, and is not a mere relative term. Moreover, one or more of the processing steps and tooling used to fabricate semiconductor devices are also described in a number of readily available publications, including, for example: James D. Plummer et al., Silicon VLSI Technology: Fundamentals, Practice, and Modeling 1^{st} Edition, Prentice Hall, 2001 and P. H. Holloway et al., Handbook of Compound Semiconductors: Growth, Processing, Characterization, and Devices, Cambridge University Press, 2008, which are both hereby incorporated by reference herein. It is emphasized that while some individual processing steps are set forth herein, those steps are merely illustrative, and one skilled in the art may be familiar with several equally suitable alternatives that would be applicable.

It is to be appreciated that the various layers and/or regions shown in the accompanying figures may not be drawn to scale. Furthermore, one or more semiconductor layers of a type commonly used in such integrated circuit devices may not be explicitly shown in a given figure for ease of explanation. This does not imply that the semiconductor layer(s) not explicitly shown are omitted in the actual integrated circuit device.

Those skilled in the art will appreciate that the exemplary structures discussed above can be distributed in raw form (i.e., a single wafer having multiple unpackaged chips), as bare dies, in packaged form, or incorporated as parts of intermediate products or end products.

An integrated circuit in accordance with aspects of the present inventions can be employed in essentially any application and/or electronic system. Given the teachings of the present disclosure provided herein, one of ordinary skill in the art will be able to contemplate other implementations and applications of embodiments disclosed herein.

The illustrations of embodiments described herein are intended to provide a general understanding of the various embodiments, and they are not intended to serve as a complete description of all the elements and features of apparatus and systems that might make use of the circuits and techniques described herein. Many other embodiments will become apparent to those skilled in the art given the teachings herein; other embodiments are utilized and derived therefrom, such that structural and logical substitutions and changes can be made without departing from the scope of this disclosure. It should also be noted that, in some alternative implementations, some of the steps of the exemplary methods may occur out of the order noted in the figures. For example, two steps shown in succession may, in fact, be executed substantially concurrently, or certain steps may sometimes be executed in the reverse order, depending upon the functionality involved. The drawings are also merely representational and are not drawn to scale. Accordingly, the specification and drawings are to be regarded in an illustrative rather than a restrictive sense.

Embodiments are referred to herein, individually and/or collectively, by the term “embodiment” merely for convenience and without intending to limit the scope of this application to any single embodiment or inventive concept if more than one is, in fact, shown. Thus, although specific embodiments have been illustrated and described herein, it should be understood that an arrangement achieving the same purpose can be substituted for the specific embodiment(s) shown; that is, this disclosure is intended to cover any and all adaptations or variations of various embodiments. Combinations of the above embodiments, and other embodiments not specifically described herein, will become apparent to those of skill in the art given the teachings herein.

The terminology used herein is for the purpose of describing particular embodiments only and is not intended to be limiting. As used herein, the singular forms “a,” “an” and “the” are intended to include the plural forms as well, unless the context clearly indicates otherwise. It will be further understood that the terms “comprises” and/or “comprising,” when used in this specification, specify the presence of stated features, steps, operations, elements, and/or components, but do not preclude the presence or addition of one or more other features, steps, operations, elements, components, and/or groups thereof. Terms such as “bottom”, “top”, “above”, “over”, “under” and “below” are used to indicate relative positioning of elements or structures to each other as opposed to relative elevation. If a layer of a structure is described herein as “over” another layer, it will be understood that there may or may not be intermediate elements or layers between the two specified layers. If a layer is described as “directly on” another layer, direct contact of the two layers is indicated. As the term is used herein and in the appended claims, “about” means within plus or minus ten percent.

The corresponding structures, materials, acts, and equivalents of any means or step-plus-function elements in the claims below are intended to include any structure, material, or act for performing the function in combination with other claimed elements as specifically claimed. The description of the various embodiments has been presented for purposes of illustration and description, but is not intended to be exhaustive or limited to the forms disclosed. Many modifications and variations will be apparent to those of ordinary skill in the art without departing from the scope and spirit thereof. The embodiments were chosen and described in order to best explain principles and practical applications, and to enable others of ordinary skill in the art to understand the various embodiments with various modifications as are suited to the particular use contemplated.

The abstract is provided to comply with 37 C.F.R. § 1.76(b), which requires an abstract that will allow the reader to quickly ascertain the nature of the technical disclosure. It is submitted with the understanding that it will not be used to interpret or limit the scope or meaning of the claims. In addition, in the foregoing Detailed Description, it can be seen that various features are grouped together in a single embodiment for the purpose of streamlining the disclosure. This method of disclosure is not to be interpreted as reflecting an intention that the claimed embodiments require more features than are expressly recited in each claim. Rather, as the appended claims reflect, the claimed subject matter may lie in less than all features of a single embodiment. Thus, the following claims are hereby incorporated into the Detailed Description, with each claim standing on its own as separately claimed subject matter.

Given the teachings provided herein, one of ordinary skill in the art will be able to contemplate other implementations and applications of the techniques and disclosed embodiments. Although illustrative embodiments have been described herein with reference to the accompanying drawings, it is to be understood that illustrative embodiments are not limited to those precise embodiments, and that various other changes and modifications are made therein by one skilled in the art without departing from the scope of the appended claims.

What is claimed is:

1. A semiconductor structure comprising:
a first active area having first and second source-drain regions;
a nanosheet region of the active area interconnecting the first and second source-drain regions;
a gate overlying and surrounding the nanosheet region;
a direct backside contact (DBC) located below the gate in the nanosheet region; and
a wrap-around dielectric liner having horizontal portions and vertical portions, wherein the horizontal portions contact the top of the direct backside contact (DBC) and the vertical portions contact sidewalls of the direct backside contact (DBC).

2. The semiconductor structure of claim 1, wherein the wrap-around material is selected from the group comprising SiCO, SiBCN SiCON, and Aluminum Oxide.

3. The semiconductor structure of claim 1, further comprising:
a gate spacer on opposing verticals sides of the gate, wherein the gate spacer and the wrap-around dielectric liner are the same material.

4. The semiconductor structure of claim 1, further comprising:
a back side power rail (BSPR) in contact with the direct backside contact (DBC).

5. The semiconductor structure of claim 1, wherein the direct backside contact (DBC) contacts the second source-drain region.

6. The semiconductor structure of claim 5, wherein the vertical portion of wrap-around dielectric liner is in contact with sidewalls of the second source-drain of the first active area and sidewalls of the direct backside contact (DBC).

7. The semiconductor structure of claim 5, further comprising:
a frontside contact to the first source-drain region wherein the frontside contact does not overlay the direct backside contact (DBC).

8. The semiconductor structure of claim 1, further comprising:
a second active area having another source drain region and a second nanosheet region wherein the gate overlies and surrounds the second nanosheet region;
a dielectric island under the second nanosheet region;
wherein the wrap-around dielectric liner is located on a top surface and a portion of the sidewalls of the dielectric island.

9. The semiconductor structure of claim 8, wherein the vertical portion of wrap-around dielectric liner is in contact with the other source-drain.

10. The semiconductor structure of claim 8, further comprising:
a placeholder material under the other source drain region wherein the vertical portion of wrap-around dielectric liner is in contact with an upper portion of the sidewall placeholder material.

11. The semiconductor structure of claim 1, further comprising:
a shallow trench isolation (STI) region separating the first and second active regions wherein the shallow trench isolation (STI) region comprises a shallow trench isolation (STI) liner and a shallow trench isolation (STI) insulator;
wherein the shallow trench isolation (STI) liner is located under the vertical portion of the wrap-around dielectric liner and contacts sidewalls of the direct backside contact BCD.

12. The semiconductor structure of claim 11, wherein the shallow trench isolation (STI) liner and the vertical portion of the wrap-around dielectric liner have the same width.

13. The semiconductor structure of claim 11, wherein the shallow trench isolation (STI) liner and the wrap-around dielectric liner are different materials.

14. The semiconductor structure of claim 11, wherein the vertical portion of the wrap-around dielectric liner is from about 1% to about 50% of a sidewall of the direct backside contact BCD.

15. A semiconductor structure comprising:
a first active area and a second active area each having first and second source-drain regions;
a shallow trench isolation (STI) region separating the first and second active areas;
a nanosheet region in each active area interconnecting the first and second source-drain regions of each active area;
a gate structure over the nanosheet region of each of the first and second active areas and the isolation region;
a dielectric island adjacent the shallow trench isolation (STI) region and under the nanosheet region of the second active area, the dielectric island having an upper portion;
a direct backside contact (DBC) located below the nanosheet region and the second source-drain region of the first active area, the direct backside contact (DBC) having an upper portion in contact with the second source-drain region of the first active area;
a power rail in contact with a lower portion of the direct backside contact (DBC); and
a wrap-around dielectric liner wrapping the upper portion of the direct backside contact (DBC) under the nanosheet region of the first active area and the upper portion of the dielectric island.

16. The semiconductor structure of claim 15, wherein the wrap-around dielectric liner has a vertical portion in contact with the second source-drain of the first active area region and the direct backside contact (DBC).

17. The semiconductor structure of claim 15, wherein the wrap-around dielectric liner has a vertical portion in contact with the second source-drain of the second active area region.

18. The semiconductor structure of claim 17, wherein the vertical portion of the wrap-around dielectric liner is in contact with a placeholder material located under the second source-drain of the second active area region.

19. A method of forming a structure, comprising:
providing a substrate having a stack of alternating layers of nanosheets and sacrificial layers on a bottom sacrificial layer on the substrate;
forming one or more openings in the substrate adjacent the stack;
forming a shallow trench liner and insulation in the one or more substrate openings;
recessing the shallow trench liner to form cavities;
filling the cavities with a gap fill material in communication with the bottom sacrificial layer;
forming a dummy gate;
removing the gap fill material and bottom sacrificial layer;
forming a wrap-around dielectric liner;
replacing the dummy gate with a metal gate; and
forming a direct backside contact (DBC) isolated from the metal gate by the wrap-around dielectric.

20. The method of claim 19, further comprising:
forming inner spacers under the alternating layers of nanosheets and adjacent the sacrificial layers; and
forming a power rail in contact with the direct backside contact (DBC).
